(19) United States
(12) Patent Application Publication
(10) Pub. No.: US 2021/0226561 A1
(43) Pub. Date: Jul. 22, 2021

(54) VIBRATIONAL ENERGY RECOVERY SYSTEM

(71) Applicant: UNIVERSITE DE CHAMBERY-UNIVERSITE SAVOIE MONT BLANC, CHAMBERY CEDEX (FR)

(72) Inventors: Adrien BADEL, LESCHERAINES (FR); Fabien FORMOSA, ANNECY-LE-VIEUX (FR)

(73) Assignee: UNIVERSITE DE CHAMBERY-UNIVERSITE SAVOIE MONT BLANC, CHAMBERY CEDEX (FR)

(21) Appl. No.: 17/059,109

(22) PCT Filed: May 15, 2019
(86) PCT No.: PCT/FR2019/051110

§ 371 Date: Nov. 25, 2020

(30) Foreign Application Priority Data
May 29, 2018 (FR) 1870614

(51) Int. Cl. H02N 2/18

(52) U.S. Cl. CPC H02N 2/186

(57) ABSTRACT

The present disclosure concerns a mechanical vibration energy device including an assembly of spring blades between two points and at least two masses respectively on either side of the blade assembly, wherein the blade assembly is buckled between the two points by the bringing of the masses towards each other.

The present patent application claims the priority benefit of French patent application FR18/70614 which is herein incorporated by reference.

### BACKGROUND

The present disclosure generally concerns energy harvesters and, more particularly, vibration energy harvester devices, capable of generating electricity from mechanical vibrations. The present invention particularly applies to the generation of energy by equipment capable of vibrating, for example, air conditioning ducts in a building, computers in operation, industrial machines, vehicle motors, transport infrastructures, etc.

### DISCUSSION OF THE RELATED ART

It is long known that it is possible to harvest energy from vibrations of a mechanical system. Certain mechanical-to-electrical converters or vibration harvesters use piezoelectric elements to convert a mechanical energy originating from the vibrations into electricity.

An example of a mechanical vibration energy harvesting electric generator is described in document WO-A-2011/073591 (B9966PCT). In the solution described in this document, a mass (27) moves between two positions, which movement is initiated by a displacement between two end points of the flexible blade (25). The buckling level varies according to the positions of the system.

Document WO-A-2006/046938 describes a piezoelectric device based on a vibration energy harvesting, where a flexible blade is placed in different buckling configurations by displacement of its ends.

Document JP-A-2014-121168 describes a solution where a rotating element causes by contact and mechanical pressure a defamation of a blade.

Document CN-A-101854130 describes a mechanical-to-electrical energy converter.

Document US-A-2012/0119620 describes a device and a method of multistage force amplification of piezoelectric stacks.

Document WO-A-2002/029965 describes a piezoelectric energy harvester.

### SUMMARY

There is a need to improve mechanical-to-electrical converters in tams of industrialization.

There also is a need to improve mechanical vibration energy harvesting electric generators in terms of reliability.

An embodiment overcomes all or part of the disadvantages of usual vibration energy harvesters.

An embodiment provides a mechanical vibration energy harvesting device comprising an assembly of spring blades between two fixed points, and at least two masses respectively on either side of the blade assembly, wherein the blade assembly is buckled between the two points by the bringing of the masses towards each other, the blade assembly having, once buckled, exactly two stable positions.

According to an embodiment, with no external mechanical action, the two stable positions of the blade assembly are symmetrical with respect to a straight line connecting the two fixed points.

According to an embodiment, said masses are distinct from blades of said blade assembly.

According to an embodiment, the interval between the two masses is, once the blade assembly has been buckled, maintained constant independently from the mechanical vibration energy applied to the device.

According to an embodiment, said two positions are stable in the absence of outer stress.

According to an embodiment, the energy harvesting is due to the passing of the blade assembly, under the effect of the mechanical vibration energy, from one of said positions to the other.

According to an embodiment, the blade assembly comprises a central portion between two end arms, the central portion comprising two central arms respectively associated with the two masses.

According to an embodiment, each central arm is attached, in its middle, to the mass with which it is associated.

According to an embodiment, each mass comprises a plate having an edge attached, by a protruding portion, to one of the central aims.

According to an embodiment, the device comprises at least one mechanical-to-electrical conversion device between an end of the blade assembly and one of said points.

According to an embodiment, the device comprises at least one mechanical-to-electrical conversion device at each end of the blade assembly.

According of an embodiment, each conversion device comprises a piezoelectric element in a direction approximately perpendicular to the direction of the blade assembly.

According to an embodiment, each conversion device comprises a frame in the foam of a double arch, the middles of the arches being respectively connected to an end of the blade assembly and to one of the points.

According to an embodiment, said points form part of two opposite edges of a frame having the blade assembly and the masses housed therein.

An embodiment provides an electric power generation system comprising equipment submitted to mechanical vibrations and a mechanical vibration energy harvesting device.

According to an embodiment, the device is attached to the equipment.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a very simplified view illustrating the operating principle of a mechanical vibration energy harvesting electric generator, of bistable type;

FIG. 2 is a very simplified planar view of an embodiment of a device of vibration energy harvesting and conversion into electric energy in monostable situation;

FIG. 3 is a very simplified planar view of the device of FIG. 2, in bistable situation;

FIG. 4 is a partial perspective view of an assembly of spring blades of the device of FIGS. 2 and 3;

FIG. 5 very schematically shows a partial enlarged view of another embodiment of a blade assembly of an energy harvesting device; and

FIG. 6 schematically illustrates an embodiment of a mechanical-to-electrical converter adapted to the described embodiments of energy harvesters.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the system, equipment, device or environment, supplying the vibration energy (the vibrations) has not been detailed, the described embodiments being compatible with usual sources of vibrations in applications of conversion into electric energy. Further, what use is made of the harvested electric energy has not been detailed either, the described embodiments being here again compatible with usual applications of energy harvesters and of conversion into electricity.

Unless indicated otherwise, when reference is made to two elements connected or attached to each other, this signifies a direct connection without any intermediate elements other than a binder of glue, solder, or screwing type, and when reference is made to two elements associated or coupled together, this signifies that these two elements can be connected or they can be coupled via one or more other elements.

In the following disclosure, unless otherwise specified, when reference is made to absolute positional qualifiers, such as the teams “front”, “back”, “top”, “bottom”, “left”, “right”, etc., or to relative positional qualifiers, such as the tams “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

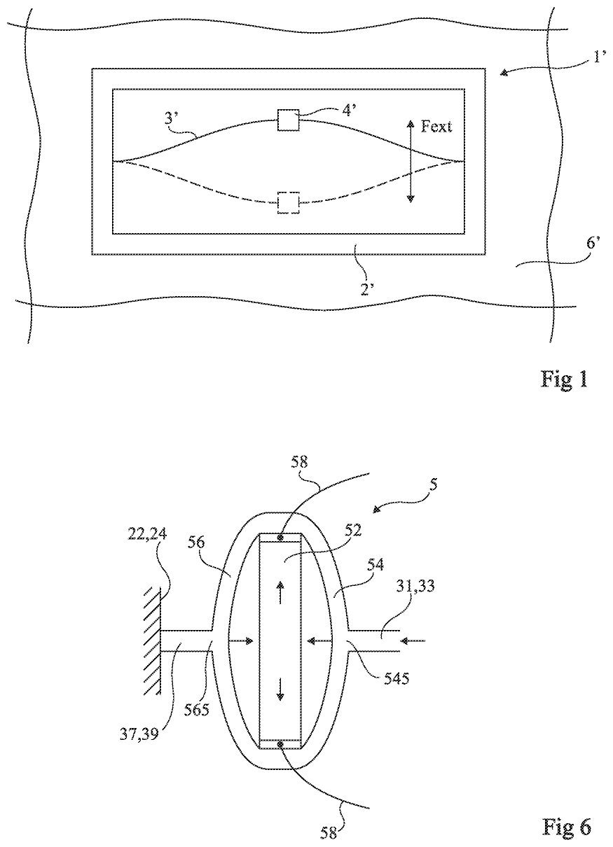

FIG. 1 is a very simplified view illustrating the operating principle of a mechanical vibration energy harvesting electric generator 1′, of bistable type.

Generator 1′ comprises a support and protection package 2′, of generally parallelepipedal shape, capable of being assembled on a vibrating surface 6′. In this example, external vibrations are capable of exerting, on package 2′, an excitation, the effect of which may be schematically represented by a force of direction Fext. Package 2′ contains a spring blade 3′ having its two ends bearing, in compression, on two opposite lateral surfaces of the package. The two bearing points of blade 3′ on package 2′ are placed along an axis substantially orthogonal to direction Fext of the vibrations. In other words, the mechanical vibration energy harvested by the device is linked to the component of force Fext orthogonal to a (imaginary) straight line connecting the two bearing points of blade 3′ on the package. A mass 4′ is attached to blade 3′, substantially in its middle. Blade 3′, in compression between its two ends, and mass 4′, define a non-linear or bistable system which may, under the effect of external vibrations, pass from one to the other of two stable positions of equilibrium (respectively shown in full line and in dotted lines in the drawing). Such a system may also oscillate around each of the two positions of equilibrium or stable positions. A piezoelectric-type mechanical-to-electrical converter (not shown) is provided to convert the motion of blade 3′ and of mass 4′ into electric energy.

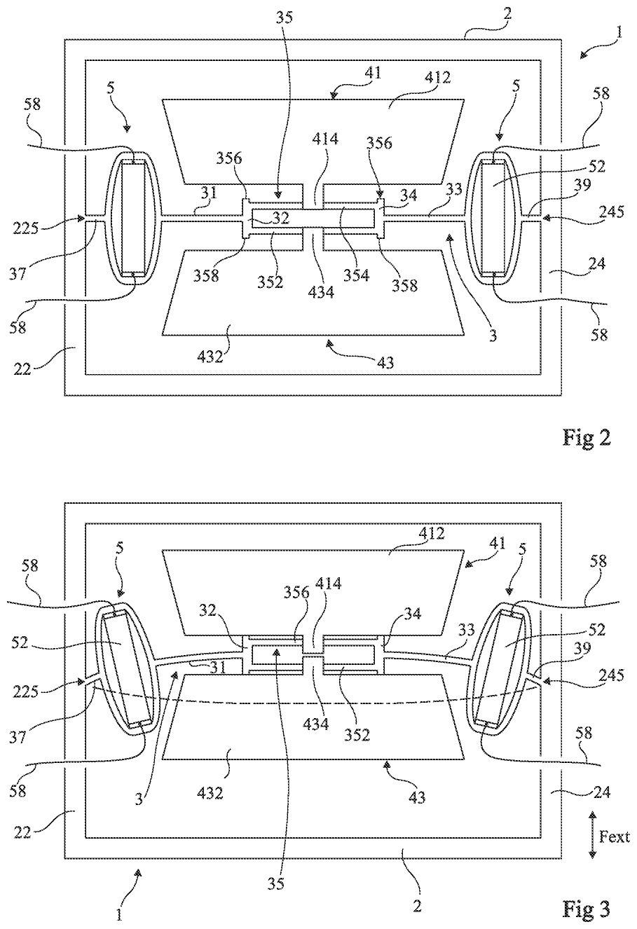

FIG. 2 is a very simplified planar view of an embodiment of a device 1 of vibration energy harvesting and of conversion into electric energy in monostable situation, before it is put into service.

FIG. 3 is a very simplified planar view of the device 1 of FIG. 2, in bistable situation, to be put into service.

To simplify the description of FIGS. 2 and 3, the equipment providing the vibrations of the system containing the energy harvesting device is not considered.

According to the described embodiments, energy harvesting device 1 comprises a support package provided with a rigid frame 2. The package is for example closed by two plates (not shown), on either side of frame 2, to protect the inside from dust or the like.

An assembly 3 of spring blades foams the vibration energy harvesting mechanism. Assembly 3 is assembled between two energy harvesting devices 5. Each of devices 5 bears on one of two opposite lateral surfaces 22 and 24 of the package, directly or via a coupling element. The two bearing points 225 and 245 of the obtained structure (assembly 3 plus devices 5) on frame 2 are placed along an axis substantially orthogonal to the expected direction Fext of the vibrations. The stress external to the device, or vibrations, having its energy harvested by the latter, is stress applied to frame 2 or to the support frame.

According to the embodiment of FIG. 2, the two points 225 and 245 are fixed points, that is, points that are fixed with respect to the frame 2 having assembly 3 and devices 5 included therein.

A specificity of this system is that it may be strained, for a putting into service, to an elongation situation to be switched from a monostable (rectilinear) situation to a bistable (buckled) situation. Thus, the blade assembly is intended to be buckled between two stable positions, that is, once buckled, the blade assembly comprises two and only two stable positions in the absence of outer stress.

More particularly, blade assembly 3 comprises two end blade aims 31 and 33, each coupled to an energy conversion device 5. Arms 31 and 33, having their distal ends coupled to devices 5, have their proximal ends coupled, preferably directly, to a central portion 35 of assembly 3. Central portion 35 comprises two central blade aims 352 and 354, each coupled (preferably directly attached) to at least one mass 41, 43. Aims 352 and 354 are, in the example of FIGS. 2 and 3, approximately parallel to each other. Arms 352 and 354 are, in this example, coupled to aims 31 and 33, by portions 32 and 34 of blades perpendicular to arms 352 and 354. In the shown example, each aim 352, 354 is associated with a mass, respectively 41, 43, having the general shape of a plate 412, 432. Plates 412 and 432 are approximately coplanar, preferably coplanar, with each other. They are preferably inscribed within a plane, approximately perpendicular, preferably perpendicular, to the blades and to all the sides of frame 2. Masses 41 and 43 are preferably identical, to respect the symmetry of the assembly. Masses 41 and 43 are distinct from blades 31 and 33 in that they are elements added to the blades, which add a mass to the mass of the actual blades. The energy harvesting of the described device is linked to the inertial movement caused by the presence of masses additional to the blade assembly and which enables to obtain a translational movement of the masses, in the plane of the device, in a direction orthogonal to the axis of the device (imaginary straight line between the two points 225 and 245).

In deactivated or inactive position (FIG. 2), before the putting into service or at the end of the manufacturing, arms 352 and 354 of blade assembly 3 are, in the example of FIGS. 2 and 3, aligned with or parallel to each other. Similarly, portions 32 and 34 are rectilinear and parallel to each other. Thus, the masses 41 and 43 which are attached to arms 352 and 354 of central portion 35 are drawn away from each other. In such a deactivated position, or out-of-service position, it can be considered that the system has a single stable position which is the position where blades or aims 31 and 32 are aligned between the two points 224 and 245.

In the embodiment of FIGS. 2 and 3, it is assumed that aims 352 and 354 are thicker than portions 32 and 34.

The activation of device 1 is performed by straining arms 352 and 354 of central portion 35 towards each other, and thus masses 41 and 43 towards each other. Since portions 32 and 34 are thinner than aims 352 and 354, the arms do not deform and remain parallel to each other. This results in deforming (lengthening) portions 32 and 34 towards the outside (towards device 5), and thus in lengthening blade assembly 3, which causes a buckling inside of frame 2 without having to deform the frame. Such a buckling makes the system bistable with two stable positions on either side of the median or inactive position (FIG. 2), defined by a straight line connecting the two points 225 and 245. Once masses 41 and 43 have been strained towards each other, and thus the structure has been buckled, the median position no longer is a stable position.

The activation of the device is preferably performed once and for all at the putting into service. The activation does not correspond to the mechanical vibrations having their energy intended to be harvested, but to a strain independent from the outer stress having its energy desired to be harvested. Such stress or vibrations cause, once the device is activated, the passing of the blade assembly from one of the stable positions to the other as well as oscillations around each stable position. During the passing from one stable position to the other, the blade assembly passes through the median position which has become, after activation, an unstable position.

In other words, in a device with two fixed points, the buckling level of the structure is not modified by the outer stress having its energy harvested.

According to a variant which will be illustrated hereafter in relation with FIG. 5, portions 32 and 34 are thicker than aims 352 and 354. A similar effect of lengthening of the blade assembly is then obtained by deformation of the arms.

Thus, unlike usual systems where the bistable character is obtained by straining the frame, the described embodiments provide acting on the spring blade assembly itself.

An advantage is that this makes the system more reliable in an industrial implementation. Indeed, a device 1 may be attached to the vibrating equipment of the system without being concerned by any adjustment of the achieved buckling, the latter being performed inside of frame 2.

Further, it is thus possible to design, and even, if desired, to assemble, device 1 on the equipment for which it is intended with no strain, that is, in a monostable situation (FIG. 2), and to only put it into service subsequently by drawing the central aims 352 and 354 of spring blade assembly 3 towards each other.

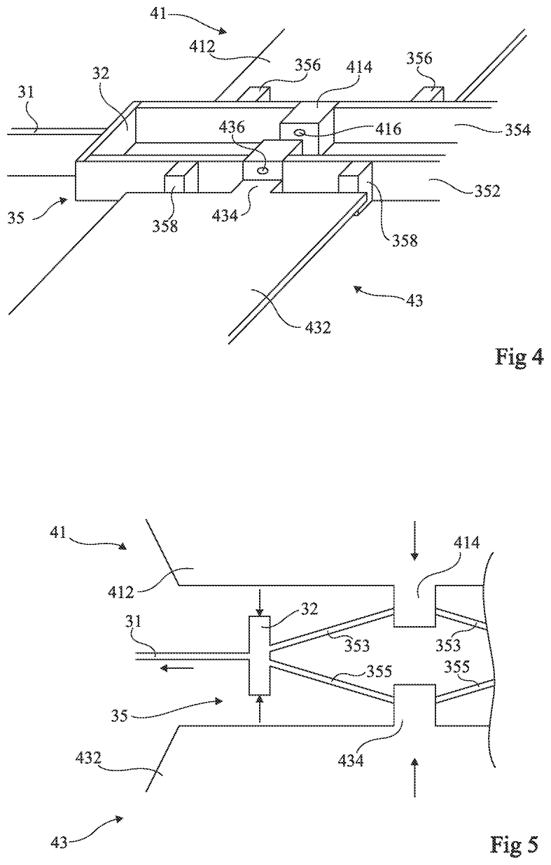

FIG. 4 is a partial perspective view of a spring blade assembly of the device of FIGS. 2 and 3.

According to a preferred embodiment, each mass 41, 43 comprises, protruding from the edge of plate 412, 432, proximal to arms 352 and 354, a tab 414, 434 perpendicular to this edge and to arms 352 and 354. Tabs 414 and 434 face each other and are intended to be abutted in active position (FIG. 3). In a way, it foams a stop for the buckling.

Preferably, the central portion 35 of the blade assembly comprises, on either side of tabs 414 and 434, portions 356 and 358 protruding out of the assembly, that is, towards respective plates 412 and 432. The role of portions 356 and 358 is to form stops bearing, when the system is in buckled position, against the edges of opposite plates 412 and 432, and thus to avoid the rotation of masses 41 and 43 in the plane of plates 412 and 432 on occurrence of rectilinear stress.

In the example illustrated in FIG. 4, stops 356 and 358 are located between portions 32 and 34 and tabs 414 and 434. In the example of FIGS. 2 and 3, stops 356 and 358 are formed by the ends of portions 32 and 34, which protrude from arms 352 and 354.

According to an embodiment, the buckling is performed by screwing tabs 414 and 434 to each other (for example, through aligned ports 416 and 436 to bring masses 41 and 43 towards each other. Tabs 414 and 434 are however not in contact in buckling situation.

In the example of FIG. 4, plates 41 and 43 thinner than arms 352 and 354 have been arbitrarily illustrated. However, in practice, the plates may be of same thickness, or even thicker than aims 352 and 354. Indeed, it is generally desired to maximize the weight of the masses to increase the effects of the converter.

FIG. 5 very schematically shows a partial enlarged view of another embodiment of the central portion 35 of a blade assembly 3 of an energy harvesting device.

FIG. 5 shows the system before buckling, that is, in a monostable central position such as illustrated in FIG. 2.

According to this example, central portion 35 comprises, on either side of tabs 414 and 434 of masses 41 and 43, central arms 353, respectively 355, coupling the tabs to portions 32 and 34 (only portion 32 is shown in FIG. 5) of connection to aims 31 and 33 (only aim 31 is shown in FIG. 5). Arms 353 and 355 describe, in inactive position, a diamond, that is, the ends of two opposite arms 31 and 33 are, on the side of tabs 414, respectively 434, more distant from each other than on the side of portion 32, 34. Arms 353 and 355 are thus not parallel to each other in inactive position. According to this embodiment, portions 32 and 34 are thicker than arms 353 and 355. The buckling of the structure (arrows in FIG. 5) is performed by bringing tabs 414 and 434, and thus plates 412 and 432, towards each other, until the edges of the plates abut against the ends of portions 32 and 34, tabs 414 and 434 remaining with a clearance between them. This cause a lengthening of the blade assembly and, since frame 2 is rigid, a buckling of blade assembly 3.

Each energy conversion device 5 comprises a piezoelectric element 52 strained, in the shown embodiments, by a frame, generally called flextensor, here in the foam of a double arch 54, 56, or of a diamond.

FIG. 6 is an enlarged view of an embodiment of an energy conversion device 5 adapted to the described energy harvesting embodiments.

The middle of arches 54 and 56 is coupled, for one, to one 31 or 33 of the end blades of blade assembly 3 and, for the other, to the edge, respectively 22, 24 of frame 2, preferably via a terminal arm 37, respectively 39. The ends of arches 54 and 56 are attached to the ends of piezoelectric element 52 (for example, a stack of interdigited piezoelectric plates, a piezoelectric bar, or any other adapted piezoelectric structure). The connections 545 and 565 of the middles of arches 54 and 56 to blades 31 and 37, respectively 33 and 39, are for example rigid (gluing or welding) or achieved via ball joints. The end electrodes of piezoelectric element 52 are coupled, by conductive wires 58 crossing frame 2, to electric/electronic circuits (not shown) for shaping the captured electric signal.

The piezoelectric effect is obtained by defaming (crushing, releasing) arches 54 and 56 from their median portions (connections 545 and 565), which causes a strain (extension, compression) of piezoelectric element 52 and generates electricity. In FIG. 6, arrows illustrate the strain when the system passes through the median (unstable) position. Piezoelectric element 52 is strained in extension under the effect of the bringing of points 545 and 565 towards each other, which causes an elongation of the frame.

It should be noted that the active direction of piezoelectric element 52 is approximately perpendicular to the direction of blade assembly 3, and thus approximately parallel to the vibration direction.

It could have been devised to interpose, in line with a spring blade, a piezoelectric element. However, this would generate too much torsion strain thereon. An advantage of the described conversion devices is that piezoelectric element 52 is protected, arches 54 and 56 providing a non-square diamond frame shape having piezoelectric element 52 (for example, the bar) attached in a diagonal thereof.

The kinematics of device 1 in operation is the following. Starting from one of the two stable positions, for example, that illustrated in full line in FIG. 3, a displacement of the blade assembly and of the masses towards the other stable position (dotted line symbolizing the position of the blade assembly) generates a crushing of arches 54 and 56 of the conversion devices 5 to pass the median position, which results in a lengthening of piezoelectric elements 52, which causes the generation of electricity. The system relaxes when reaching the other stable position. Frame 2 is secured, for example, screwed or glued), to the vibrating equipment (6′, FIG. 1). The vibrations cause an oscillation of the system between the two stable positions, and thus the generation of electricity.

An advantage of the described embodiments is that they enable not to act on package frame 2 to buckle the blade system. This eases the assemblies of energy harvesters on equipment generating vibrations.

Another advantage is that by buckling blade assembly 3 by a strain at its center, the symmetry of the system is kept, which favors an oscillating operation between the two stable positions.

Although a preferred embodiment with two conversion devices on either side of the blade assembly has been discussed, which preserves the symmetry of the device, a single device 5 may be provided at one end of the blade assembly, the other end being directly connected to frame 2.

According to another variant, two or more devices are provided between an end of blade assembly 3 and frame 2.

Reference has been made to a frame 2 since, in most applications, this frame takes part in the definition of a package capable of being closed with two plates on either side of the frame. However, from a functional point of view, what matters is for the two sides (the two small sides 22 and 24 in the shown example) or points 225 and 245 between which blade structure 3 extends not to be deformed to buckle the blade assembly. Thus, points 225 and 245 are fixed.

As an example, the blade aims may be formed from a steel band in the order of from 5 to 50 mm, for example, in the order of 20 mm, and having a thickness in the order of from 100 to 500 μm, for example, in the order of 200 μm. Blade assembly 3 may have, between the two conversion devices 5, a length from 5 to 20 cm, for example, in the order of 10 cm. Masses 41 and 43 may each have a weight in the order of from 10 to 250 g, for example, in the order of 50 g. Masses 41 and 43 may be attached to aims 352 and 354 (or 353 and 355) by gluing, welding, screwing, or any other adapted means. Of course, the above dimensions are given as an example only. In practice, the dimensions of the system may be in the range from a few tenths of mm and a few tens of cm.

Various embodiments and variants have been described. These various embodiments and variants may be combined and other variants will occur to those skilled in the art. In particular, other geometries of frame 2 may be provided. Further, although in principle, the structure will be buckled at the end of the assembly once and for all, a reversible buckling enabling to take the masses away from each other (for example, by unscrewing), either to place the harvester at rest, or during maintenance operations, may be provided. Finally, the practical implementation of the described embodiments and variants is within the abilities of those skilled in the art based on the functional indications given hereabove, in particular concerning dimensions to be given to the different elements according to the application.

What is claimed is:

1. A mechanical vibration energy harvesting device comprising:
an assembly of spring blades between two fixed points, and at least two masses respectively on either side of the blade assembly, wherein the blade assembly is buckled between the two points by the bringing of the masses towards each other, the blade assembly having, once buckled, exactly two stable positions.

2. The device according to claim 1, wherein, in the absence of an external mechanical action, the two stable positions of the blade assembly are symmetrical with respect to a straight line connecting the two fixed points.

3. The device according to claim 1, wherein said masses are distinct from blades of said blade assembly.

4. The device according to claim 1, wherein the interval between the two masses is, once the blade assembly has been buckled, maintained constant independently from the mechanical vibration energy applied to the device.

5. The device according to claim 1, wherein said two positions are stable in the absence of outer stress.

6. The device according to claim 1, wherein the energy harvesting is due to the passing of the blade assembly, under the effect of the mechanical vibration energy, from one of said two positions to the other.

7. The device according to claim 1, wherein the blade assembly comprises a central portion between two end arms, the central portion comprising two central arms respectively associated with the two masses.

8. The device according to claim 7, wherein each central arm is attached, in its middle, to the mass with which it is associated.

9. The device according to claim 7, wherein each mass comprises a plate, having an edge attached, by a protruding portion, to one of the central arms.

10. The device according to claim 1, comprising at least one mechanical-to-electrical conversion device between an end of the blade assembly and one of said points.

11. The device according to claim 1, comprising at least one mechanical-to-electrical conversion device at each end of the blade assembly.

12. The device according to claim 10, wherein each conversion device comprises a piezoelectric element in a direction approximately perpendicular to the direction of the blade assembly.

13. The device according to claim 12, wherein each conversion device comprises a frame in the form of a double arch, the middles of the arches being respectively coupled to an end of the blade assembly and to one of the points.

14. The device according to claim 1, wherein said points form part of two opposite edges of a frame having the blade assembly and the masses housed therein.

15. An electric power generation system comprising:
equipment submitted to mechanical vibrations; and
the device according to claim 1.

16. The system according to claim 15, wherein the device is attached to the equipment.

17. The device according to claim 7, wherein each mass comprises a plate, having an edge attached, by a protruding portion, to one of the central arms.

18. The device according to claim 10, wherein each conversion device comprises a piezoelectric element in a direction approximately perpendicular to the direction of the blade assembly.

19. The device according to claim 18, wherein each conversion device comprises a frame in the form of a double arch, the middles of the arches being respectively coupled to an end of the blade assembly and to one of the points.
